(19) United States
(12) Patent Application Publication
(10) Pub. No.: US 2025/0342295 A1
(43) Pub. Date: Nov. 6, 2025

(54) SPATIAL GRADIENT OF TIME AVERAGE VELOCITY TECHNIQUES FOR DEVELOPMENT PLAN GENERATION

(71) Applicant: Schlumberger Technology Corporation, Sugar Land, TX (US)

(72) Inventors: Krishna Ramani, Crawley (GB); Daniele Boiero, Houston, TX (US)

(21) Appl. No.: 18/655,784

(22) Filed: May 6, 2024

(51) Int. Cl. G06F 30/28; E21B 41/00; G01V 1/18; G01V 1/30; G01V 20/00

(52) U.S. Cl. CPC G06F 30/28; G01V 1/301; G01V 1/303; G01V 1/306; G01V 20/00; E21B 41/00; G01V 1/189

(57) ABSTRACT

Disclosed are methods, systems, and computer programs for dynamically generating a development plan for a resource site. The methods for example, include receiving seismic data associated with a subsurface of the resource site. The seismic data may be associated with a propagated wavefield within the subsurface of the resource site and can include at least structural geological data associated with the resource site. The methods also include directionally determining a plurality of rate of change data based on the propagated wavefield within the subsurface. The methods further include executing an averaging operation using the plurality of rate of change data and thereby generate an impedance model. The impedance model may be used to generate a development plan which is then used for energy development operations at the resource site.

### INTRODUCTION

This disclosure is directed to methods, systems, and computer programs that dynamically generate a development plan for a resource site based on spatial gradient of time average velocity of a propagated seismic wave.

### BACKGROUND

The development of renewable and non-renewable energy resources, both onshore and offshore, requires considering geological conditions that control safe deployment and utilization of equipment and/or systems (e.g., equipment installations and cable corridors) associated with developing said renewable and non-renewable energy resources. For example, surface waves present in seismic data should be considered as a source of information that can be exploited for a variety of geophysical solutions that characterize the subsurface of a resource site.

Some solutions for analyzing waves (e.g., surface waves) include estimation techniques based on dispersion curves without the use of inversion data. These approaches provide data projections based on a datum plan within an investigation depth associated with surface waves and are less useful when it comes to data interpretation for geological modeling and/or equipment deployment at or around the subsurface regions of a resource site.

### SUMMARY

Disclosed are methods, systems, and computer programs for generating a development plan for a resource site based on spatial gradient of time average velocity of a propagated seismic wave. According to an embodiment, a method for generating a development plan comprises: receiving seismic data associated with a subsurface of the resource site, the seismic data being associated with a propagated wavefield within the subsurface of the resource site and comprises at least structural geological data associated with the resource site; generating, based on the seismic data, one or more data matrices or data cubes comprising data elements associated with the received seismic data; determining, using the one or more data matrices or data cubes, a first rate of change data of the propagated wavefield within the subsurface in a first direction; determining, using the one or more data matrices or data cubes, a second rate of change data of the propagated wavefield within the subsurface in a second direction; and determining, using the one or more data matrices or data cubes, a third rate of change data of the propagated wavefield within the subsurface in a third direction. The methods further include: executing, using the first rate of change data, the second rate of change data, and the third rate of change data, an averaging operation to generate an impedance model for the subsurface; generating, using the impedance model of the subsurface, a multi-dimensional image of the subsurface that is resolvable into at least two dimensions; analyzing or interpreting the multi-dimensional image of the subsurface to determine subsurface features comprised in the multi-dimensional image and thereby generate a geo-layering model for the resource site; dynamically constructing, using the geo-layering model, the development plan for the resource site; and initiating, using the development plan, an energy development operation including deploying one or more energy development equipment at the resource site.

In other embodiments, a system and a computer program can include or execute the method described above. These and other implementations may each optionally include one or more of the following features.

The seismic data comprises one or more of: surface waves including waves whose amplitude decrease with increasing depth within the subsurface of the resource site; guided waves including mechanical or elastic waves within an ultrasonic or a sonic frequency band and which are propagated within a bounded medium; and interface waves indicating geological boundaries comprised in the subsurface of the resource site. In particular, the seismic data can comprise surface waves captured by one or more sensors deployed at the resource site. Furthermore, the one or more sensors deployed at the resource site can comprise one of a distributed acoustic sensor, a hydrophonic sensor, or a geophonic sensor. Moreover, the surface waves can indicate the propagated wavefield within the subsurface of the resource site based on a frequency bandwidth of the propagated wavefield.

In one embodiment, one or more of the first rate of change data, the second rate of change data, and the third rate of change data may be determined based on dispersion analysis of the surface waves. The dispersion analysis may be used to determine an estimation of a time average velocity of a propagated wavefield in the first direction, the second direction, and the third direction.

In some cases, a multi-dimensional smoothing process comprising a de-noising operation may be applied to the seismic data prior to determining the first rate of change data, the second rate of change data, or the third rate of change data.

The first direction, the second direction, and the third direction, according to some embodiments, are each orthogonal relative to each other.

According to some embodiments, the averaging operation comprises combining directional rate of change data of the propagated wavefield within the subsurface based on the first rate of change data, the second rate of change data, and the third rate of change data.

Furthermore, analyzing or interpreting the multi-dimensional image of the subsurface comprises: determining geologic features included in the multi-dimensional image; resolving the geologic features into one or more geological layering data comprised in the subsurface of the resource site; and generating the geo-layering model using the geological layering data.

In addition, the energy development operation can comprise determining geological foundation data for installing equipment associated with a windfarm at the resource site. According to other embodiments, the energy development operation comprises determining a risk map for extracting a resource from the resource site. The risk map, for example, can indicate location data at the resource site that qualifies or quantifies: first risk information for extracting the resource at a first location comprised in the location data and associated with the resource site relative to second risk information for extracting the resource at a second location comprised in the location data and associated with the resource site; and determining hazard information. The hazard information may be used to optimize one or more of: compliance operations associated with the resource site; or security operations including safety operations or insurance operations associated with the resource site.

According to one embodiment, the multi-dimensional image comprises a 2-dimensional or a 3-dimensional image. Furthermore, the multi-dimensional image is resolvable based on the first direction, the second direction, and the third direction.

In some implementations, generating one or more of the first rate of change data, the second rate of change data, and the third rate of change data is based on directionally executing a differentiation operation on the one or more data matrices or data cubes in the first direction, the second direction, or the third direction.

### BRIEF DESCRIPTION OF THE DRAWINGS

The disclosure is illustrated by way of example, and not by way of limitation in the figures of the accompanying drawings in which like reference numerals are used to refer to similar elements. It is emphasized that various features may not be drawn to scale and the dimensions of various features may be arbitrarily increased or reduced for clarity of discussion.

FIG. 1 shows an exemplary high-level flowchart for dynamically generating a development plan.

FIG. 2 shows a cross-sectional view of a resource site for which the process of FIG. 4 may be executed.

FIG. 3 shows a networked system illustrating a communicative coupling of devices or systems associated with the resource site of FIG. 2.

FIGS. 4A-4B provide an exemplary workflow for methods, systems, and computer programs that dynamically generate a development plan for a resource site based on spatial gradient of time average velocity determinations of a propagated seismic wave.

FIGS. 5A-5B show an exemplary transformation of captured seismic data to a geo-layering data.

FIGS. 6A-6C shows the use of a reference model to confirm a generated impedance model.

### DETAILED DESCRIPTION

Reference will now be made in detail to embodiments, examples of which are illustrated in the accompanying drawings and figures. In the following detailed description, numerous specific details are set forth in order to provide a thorough understanding of the disclosed subject-matter. However, it will be apparent to one of ordinary skill in the art that the solutions disclosed may be practiced without these specific details. In other instances, well-known methods, procedures, components, circuits and networks have not been described in detail so as not to unnecessarily obscure aspects of the embodiments.

The disclosed systems and methods may be accomplished using interconnected devices and systems that obtain a plurality of data associated with various parameters of interest at a resource site. The workflows/flowcharts described in this disclosure, according to some embodiments, implicate a new processing approach (e.g., hardware, special purpose processors, and specially programmed general-purpose processors) because such analyses are too complex and cannot be done by a person in the time available or at all. Thus, the described systems and methods are directed to tangible implementations or solutions to specific technological problems in developing natural resources such as oil, gas, water well industries, and other mineral exploration operations. More specifically, the systems and methods presently disclosed may be applicable to operations associated with seismic data analysis.

Attention is now directed to methods, techniques, infrastructure, and workflows for operations that may be carried out at a resource site. Some operations in the processing procedures, methods, techniques, and workflows disclosed herein may be combined while the order of some operations may be changed. Some embodiments include an iterative refinement of one or more data associated with the resource site via feedback loops executed by one or more computing device processors and/or through other control devices/mechanisms that make determinations regarding whether a given action, template, or resource data, etc., is sufficiently accurate.

The development of renewable energy resources can require installations that affect geological structures within the subsurface (e.g., 60 to 95 meters deep underground) of the earth. Therefore, when designing and installing these types of installations or equipment, there is a need to understand geotechnical and/or structural properties of the subsurface associated with, for example, a seabed or some other underground structures of the earth.

According to one embodiment, reflection techniques associated with seismic wavefield propagation may be used to detect stratigraphic subsurface structures for hydrocarbon exploration or other geological research. In such implementations, an active or passive signal source together with one or more multi-channel sensors may be used. However, the reflection techniques associated with seismic wavefield propagation may be complemented by surface wave studies that provide near-seabed elastic parameters offering a more direct link between seismic data and other geotechnical and/or geomechanical data. It is appreciated that the near-seabed elastic parameters can be used to tie or otherwise link findings from geotechnical boreholes to determinations associated with small strain moduli that are recognizable as parameters indicating stress-strain relationships of soils.

In some implementations, a direct estimation of a time-average S-wave velocity model and a P-wave velocity model derived from inverted or non-inverted surface wave dispersion curves may be developed. The S-wave velocity model may comprise a lateral wave that moves side to side as a sine wave perpendicular to the direction of the propagated seismic wavefield. The P-wave velocity model may comprise a primary wave or pressure wave comprising one of two main types of seismic waves. In addition, surface waves (SWs) in seismic records (e.g., captured seismic data) can be processed to extract local dispersion curves (DCs) which can then be used to estimate near-surface S-wave velocity models. A time-average velocity V_{Sz} can directly provide the value of an S-wave for a one-way time given a datum plan depth by the relationship:

$${V}_{Sz} = \frac{{\sum }_{1}^{n} {h}_{i}}{{\sum }_{1}^{n} \frac{{h}_{i}}{{V}_{Si}}} , \qquad ( 1 )$$

where V_{Si} is the S-wave interval velocity model in a subsurface layer of thickness hᵢ.

The method associated with the above equation can require knowledge of a one 1-dimensional (1D)S-wave velocity model in an area, together with corresponding DCs, to estimate a relationship between SW wavelength and investigation depth on a time-average velocity model. This wavelength-depth relationship may then be used to estimate other time-average S-wave velocity models in an area directly associated with the DCs by means of a data transformation operation. This approach, according to some implementations, can remove a need for extensive data inversion and can provide a method for subsurface workflows.

Some approaches focus on the possibility of also extracting a time-average P-wave velocity model from SW dispersion data. Such approaches have wavelength-depth relationships that can be sensitive to Poisson's ratio and provide a method for estimating an “apparent” Poisson ratio v_{z} profile, which indicates a Poisson ratio value that relates the time-average S-wave velocity to a time-average P-wave velocity V_{Pz}. Hence, time average S-wave velocity models estimated from the DCs using such an approach may be transformed into the time-average P-wave velocity model over an area based on:

$${V}_{Pz} = {V}_{Sz} \sqrt{2 \frac{( {υ}_{z} - 1 )}{2 {υ}_{z} - 1}} , \qquad ( 2 )$$

where v_{z} is the Poisson ratio at a certain depth.

According to some embodiments, implementations based on equation (2) can represent a double data transformation that provides an effective S-wave and P-wave statics estimation at a datum plan within an investigation depth of surface waves but is less useful when it comes to data interpretation for geological modeling. According to some embodiments, the disclosed approach addresses a number of issues by calculating a spatial gradient of the time average velocity V_{z} (e.g., V_{Pz} and/or V_{Sz}) and thereby determine a pseudo reflectivity out of velocity models associated with a propagated wavefield. Assuming a density parameter is a constant or a smooth function, and focusing on the relationship between reflectivity and velocity (e.g., a velocity-to-density relationship), an impedance contrast can be approximated using an acoustic impedance generation relationship:

$$\frac{\partial I}{\partial n} \approx ρ ( \frac{\partial {V}_{z}}{\partial x} sin ϑ cos φ + \frac{\partial {V}_{z}}{\partial y} sin ϑ sin φ + \frac{\partial {V}_{z}}{\partial z} cos ϑ ) , \qquad ( 3 )$$

where the impedance comprises a multiplication of density and velocity data given by I=ρν, and ε and φ represent a dip angle and azimuth angle, respectively, of a normal vector n relative to one or more subsurface reflectors, which can be obtained by automatically scanning through a velocity model. It is appreciated that the above equation represents the computation of rate of change data associated with a propagated seismic wavefield within the subsurface in directions x, y, and z in the subsurface such that the directions x, y, and z are orthogonal relative to each other. The velocity model, for example, comprises a spatial and/or temporal distribution of attributes that describe the velocity of propagation of seismic waves in the subsurface of the resource site.

The foregoing technique, according to some embodiments, provides a more interpretable product that can be used to geologically model or tie surface wave results with high-resolution seismic data and/or other borehole seismic and non-seismic (e.g., geophysical and geotechnical) sensor measurements.

### High-Level Flowchart

Disclosed are methods, systems, and apparatuses that determine a spatial gradient of a time average velocity model associated with a propagated seismic wavefield. In one embodiment, pseudo reflectivity data may be determined based on the velocity model to generate a more interpretable seismic dataset which can be used for geological modelling and/or tied to surface wave data comprising a high-resolution seismic data or borehole seismic data and/or other non-seismic (e.g., geophysical and geotechnical) measurement data.

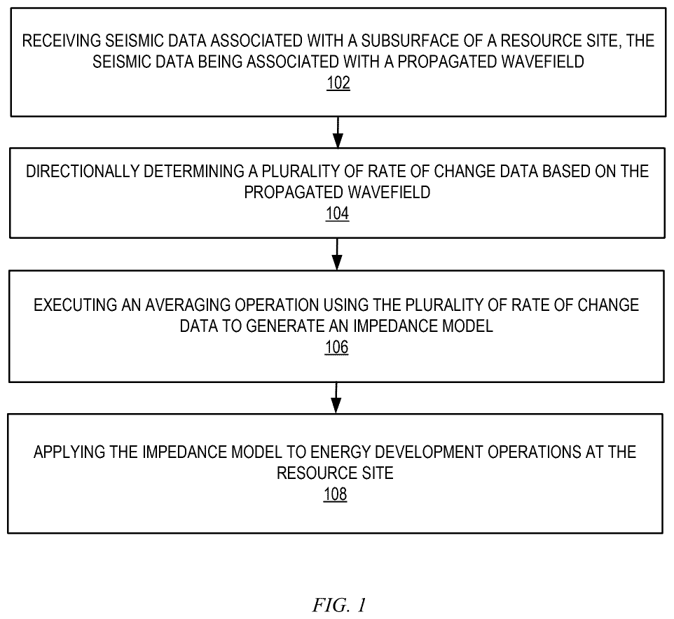

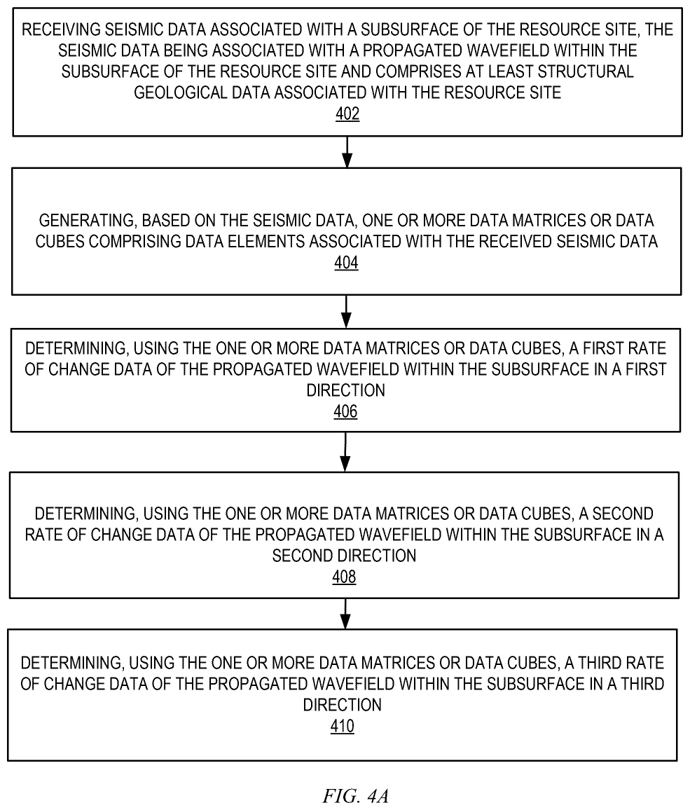

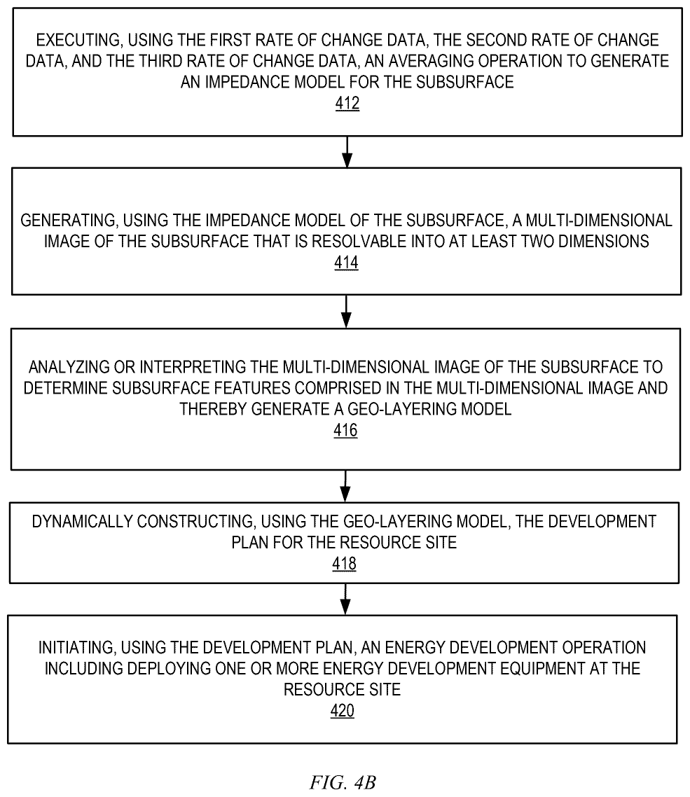

FIG. 1 shows an exemplary high-level flowchart for dynamically generating a development plan. At block 102, a signal processing engine or a data processing module may be used to receive seismic data associated with a subsurface of a resource site. The seismic data, for example, may be associated with a propagated wavefield within the subsurface of the resource site and can comprise at least structural geological data associated with the resource site. At block 104, the signal processing engine may be used to directionally determine a plurality of rate of change data based on the propagated wavefield within the subsurface. Turning to block 106, the signal processing engine may be used to execute an averaging operation using the plurality of rate of change data and thereby generate an impedance model. In one embodiment, the impedance model indicates geological data including geological properties of the subsurface and/or interaction properties of the seismic wavefield with one or more geological structures within the subsurface. The signal processing engine may be further used to apply the impedance model to energy development operations at the resource site. These aspects are further discussed in detail in association with FIG. 4, for example.

### Resource Site

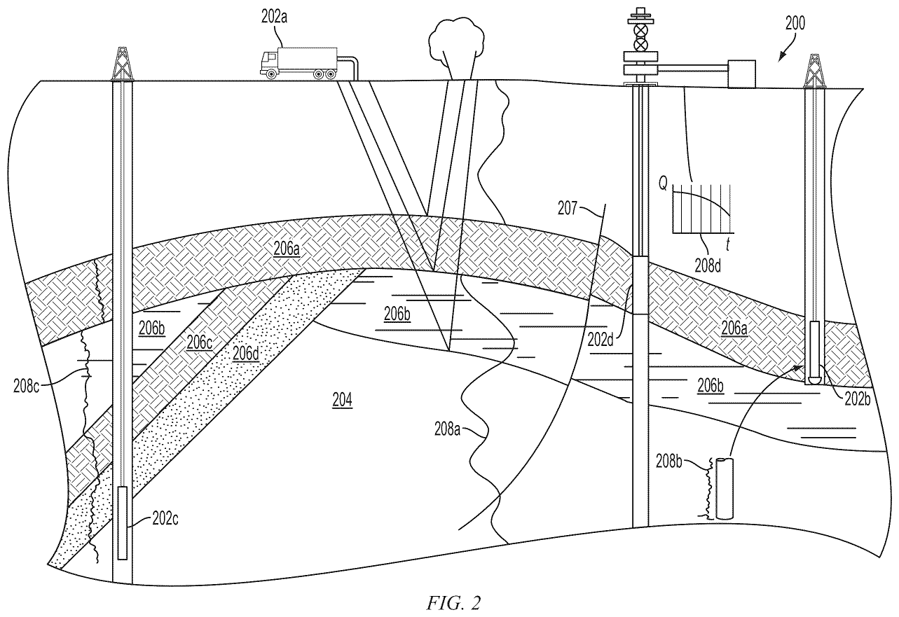

FIG. 2 shows a cross-sectional view of a resource site 200 for which the process of FIG. 1 may be executed. While the illustrated resource site 200 represents a subterranean formation, the resource site, according to some embodiments, may be below water bodies such as oceans, seas, lakes, ponds, wetlands, rivers, etc. According to one embodiment, various measurement tools capable of sensing one or more parameters such as seismic two-way travel time, density, resistivity, production rate, etc., of a subterranean formation and/or geological formations may be provided at the resource site. As an example, wireline tools may be used to obtain measurement information related to geological attributes (e.g., geological attributes of a wellbore and/or reservoir) including geophysical and/or chemical information. For example, the chemical information may include chemical information associated with the subsurface and/or chemical information associated with the surface/above ground areas of the resource site 200.

In some embodiments, various sensors may be located at various locations around the resource site 200 to monitor and collect data for executing the process of FIG. 4. In other embodiments, the techniques disclosed may be applied to surface seismic monitoring applications, surface gravity applications, surface electromagnetic applications, surface ground heave applications, and surface measurement of induced seismicity applications. According to some implementations, the disclosed techniques may be applied to remote sensing applications (e.g., satellite-based measurements), subsea applications associated with permanent sensors, temporary sensor applications, applications associated with remotely operated vehicles, and applications associated with aerial-based measurements (e.g., performed from planes, helicopters, and/or drones).

Part, or all, of the resource site 200 may be on land, on water, or below water. In addition, while a resource site 200 is depicted, the technology described herein may be used with any combination of one or more resource sites (e.g., multiple oil fields or multiple wellsites, one or more saline aquifers, one or more depleted oil/gas fields, etc.), one or more processing facilities, etc. As can be seen in FIG. 2, the resource site 200 may have data acquisition tools 202a, 202b, 202c, and 202d positioned at various locations within the resource site 200. The subterranean structure 204 may have a plurality of geological formations 206a-206d. As shown, this structure may have several formations or layers, including a shale layer 206a, a carbonate layer 206b, a shale layer 206c, and a sand layer 206d. A fault 207 may extend through the shale layer 206a and the carbonate layer 206b. The data acquisition tools, for example, may be adapted to take measurements and detect geophysical and/or chemical characteristics of the various formations shown.

While a specific subterranean formation with specific geological structures is depicted, it is appreciated that the oil field 200 may contain a variety of geological structures and/or formations, sometimes having extreme complexity. In some locations of a given geological structure, for example below a water line (e.g., aquifer) relative to the given geological structure, fluid may occupy pore spaces of the formations. Each of the measurement devices may be used to measure properties of the formations and/or other geological features. While each data acquisition tool is shown as being in specific locations in FIG. 2, it is appreciated that one or more types of measurement may be taken at one or more locations across one or more sources of the resource site 200 or other locations for comparison and/or analysis. The data collected from various sources at the resource site 200 may be processed and/or evaluated and/or used as training data, and or used to generate high resolution result sets for characterizing a resource at the resource site, and/or used for generating resource models, etc. In one embodiment, the data collected by a set of sensors at the resource site may include data associated with the number of wells of a first reservoir or second reservoir at the resource site, data associated with the number of grid cells of the first or second reservoir, data associated with the average permeability of the first or second reservoir, data associated with the production duration history (e.g., number of years of production) of the first reservoir or second, etc.

Data acquisition tool 202a is illustrated as a measurement truck, which may comprise devices or sensors that take measurements of the subsurface through sound vibrations such as, but not limited to, seismic measurements. Drilling tool 202b may include a downhole sensor adapted to perform logging while drilling (LWD) data collection. The wireline tool 202c may include a downhole sensor deployed in a wellbore or borehole. Production tool 202d may be deployed from a production unit or Christmas tree into a completed wellbore. Examples of parameters that may be measured include weight on bit, torque on bit, subterranean pressures (e.g., underground fluid pressure), temperatures, flow rates, compositions, rotary speed, particle count, voltages, currents, and/or other parameters of operations as further discussed below.

Sensors may be positioned about the resource site to collect data relating to various resource site operations, such as sensors deployed by the data acquisition tools 202. The sensor may include any type of sensor such as a metrology sensor (e.g., temperature, humidity), an automation enabling sensor, an operational sensor (e.g., pressure sensor, H₂S sensor, thermometer, depth, tension), evaluation sensors, that can be used for acquiring data regarding the formation, wellbore, formation fluid/gas, wellbore fluid, gas/oil/water comprised in the formation/wellbore fluid, or any other suitable sensor. For example, the sensors may include accelerometers, flow rate sensors, pressure transducers, electromagnetic sensors, acoustic sensors, temperature sensors, chemical agent detection sensors, nuclear sensor, and/or any additional suitable sensors. In one embodiment, the data captured by the one or sensors may be used to characterize, or otherwise generate one or more parameter values for a high resolution result set used to, for example, label or configure a machine learning (ML) engine or a resource model as the case may require. In other embodiments, test data or synthetic data may also be used in developing the ML engine or resource model via one or more parameterization/labeling operations such as those discussed in association with the workflows presented herein.

Evaluation sensors may be featured in downhole tools such as tools 202b-202d and may include for instance electromagnetic, acoustic, nuclear, and optic sensors. Examples of tools including evaluation sensors that can be used in the framework of the current method include electromagnetic tools including imaging sensors such as FMI™ or QuantaGeo™ (mark of Schlumberger, Houston, TX); induction sensors such as Rt Scanner™ (mark of Schlumberger, Houston, TX), multifrequency dielectric dispersion sensor such as Dielectric Scanner™ (mark of Schlumberger, Houston, TX); acoustic tools including sonic sensors, such as Sonic Scanner™ (mark of Schlumberger, Houston, TX) or ultrasonic sensors, such as pulse-echo sensor as in UBI™ or PowerEcho™ (marks of Schlumberger, Houston, TX) or flexural sensors PowerFlex™ (mark of Schlumberger, Houston, TX); nuclear sensors such as Litho Scanner™ (mark of Schlumberger, Houston, TX) or nuclear magnetic resonance sensors; fluid sampling tools including fluid analysis sensors such as InSitu Fluid Analyzer™ (mark of Schlumberger, Houston, TX); distributed sensors including fiber optic. Such evaluation sensors may be used in particular for evaluating the formation in which the well is formed (i.e., determining petrophysical or geological properties of the formation), for verifying the integrity of the well (such as casing or cement properties) and/or analyzing the produced fluid (flow, type of fluid, etc.).

As shown, data acquisition tools 202a-202d may generate data plots or measurements 208a-208d, respectively. These data plots are depicted within the resource site 200 to demonstrate that data generated by some of the operations executed at the resource site 200.

Data plots 208a-208c are examples of static data plots that may be generated by data acquisition tools 202a-202c, respectively. However, it is herein contemplated that data plots 208a-208c may also be data plots that may be generated and updated in real time. These measurements may be analyzed to better define properties of the formation(s) and/or determine the accuracy of the measurements and/or check for and compensate for measurement errors. The plots of each of the respective measurements may be aligned and/or scaled for comparison and verification purposes. In some embodiments, base data associated with the plots may be incorporated into site planning, modeling a test at the resource site 200. The respective measurements that can be taken may be any of the above.

Other data may also be collected, such as historical data of the resource site 200 and/or sites similar to the resource site 200, user inputs, information (e.g., economic information) associated with the resource site 200 and/or sites similar to the resource site 200, and/or other measurement data and other parameters of interest. Similar measurements may also be used to measure changes in formation aspects over time.

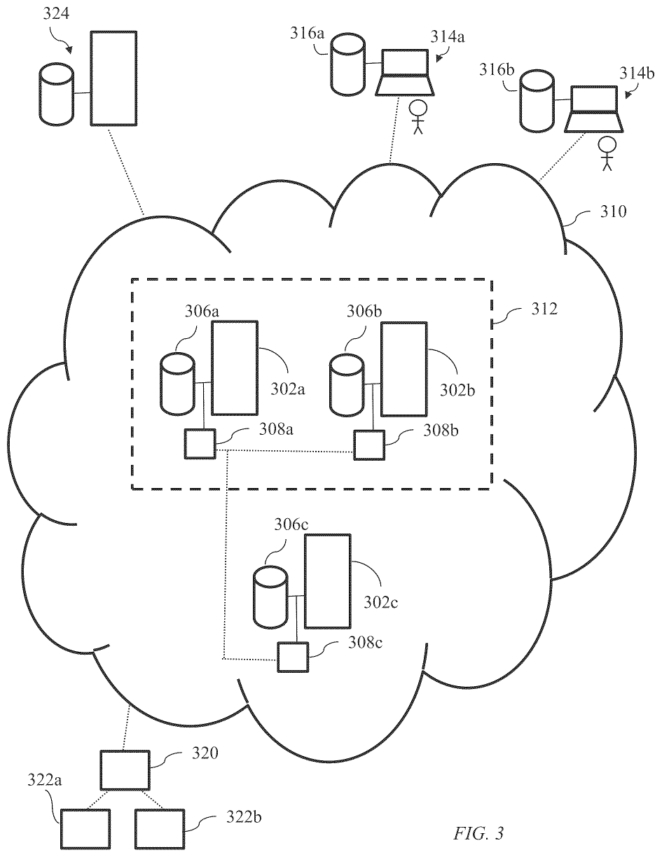

Computer facilities such as those discussed in association with FIG. 3 may be positioned at various locations about the resource site 200 (e.g., a surface unit) and/or at remote locations. A surface unit (e.g., one or more terminals 320) may be used to communicate with the onsite tools and/or offsite operations, as well as with other surface or downhole sensors. The surface unit may be capable of sending commands to the oil field equipment/systems, and receiving data therefrom. The surface unit may also collect data generated during production operations and can produce output data, which may be stored or transmitted for further processing.

The data collected by sensors may be used alone or in combination with other data. The data may be collected in one or more databases and/or transmitted on or offsite. The data may be historical data, real time data, or combinations thereof. The real time data may be used in real time, or stored for later use. The data may also be combined with historical data or other inputs for further analysis or for modeling purposes to optimize production processes at the oil field 200. In one embodiment, the data is stored in separate databases, or combined into a single database.

### High-Level Networked System

FIG. 3 shows a high-level networked system diagram illustrating a communicative coupling of devices or systems associated with the resource site 200 as described in FIG. 2. The system shown in the figure may include a set of processors 302a, 302b, and 302c for executing one or more processes discussed herein. The set of processors 302 may be electrically coupled to one or more servers (e.g., computing systems) including memory 306a, 306b, and 306c that may store for example, program data, databases, and other forms of data. Each server of the one or more servers may also include one or more communication devices 308a, 308b, and 308c. The set of servers may provide a cloud-computing platform 310. In one embodiment, the set of servers includes different computing devices that are situated in different locations and may be scalable based on the needs and workflows associated with the oil field 200. The communication devices of each server may enable the servers to communicate with each other through a local or global network such as an Internet network. In some embodiments, the servers may be arranged as a town 312, which may provide a private or local cloud service for users. A town may be advantageous in remote locations with poor connectivity. Additionally, a town may be beneficial in scenarios with large networks where security may be of concern. A town in such large network embodiments can facilitate implementation of a private network within such large networks. The town may interface with other towns or a larger cloud network, which may also communicate over public communication links. Note that cloud-computing platform 310 may include a private network and/or portions of public networks. In some cases, a cloud-computing platform 310 may include remote storage and/or other application processing capabilities.

The system of FIG. 3 may also include one or more user terminals 314a and 314b each including at least a processor to execute programs, a memory (e.g., 316a and 316b) for storing data, a communication device and one or more user interfaces and devices that enable the user to receive, view, and transmit information. In one embodiment, the user terminals 314a and 314b is a computing system having interfaces and devices including keyboards, touchscreens, display screens, speakers, microphones, a mouse, styluses, etc. The user terminals 314 may be communicatively coupled to the one or more servers of the cloud-computing platform 310. The user terminals 314 may be client terminals or expert terminals, enabling collaboration between clients and experts through the system of FIG. 3.

The system of FIG. 3 may also include at least one or more resource sites 200 having, for example, a set of terminals 320, each including at least a processor, a memory, and a communication device for communicating with other devices communicatively coupled to the cloud-computing platform 310. The resource site 200 may also have a set of sensors (e.g., one or more sensors described in association with FIG. 2) or sensor interfaces 322a and 322b communicatively coupled to the set of terminals 320 and/or directly coupled to the cloud-computing platform 310. In some embodiments, data collected by the set of sensors/sensor interfaces 322a and 322b may be processed to generate a one or more resource models (e.g., reservoir models) or one or more resolved data sets used to generate the resource model which may be displayed on a user interface associated with the set of terminals 320, and/or displayed on user interfaces associated with the set of servers of the cloud computing platform 310, and/or displayed on user interfaces of the user terminals 314. Furthermore, various equipment/devices discussed in association with the resource site 200 may also be communicatively coupled to the set of terminals 320 and or communicatively coupled directly to the cloud-computing platform 310. The equipment and sensors may also include one or more communication device(s) that may communicate with the set of terminals 320 to receive orders/instructions locally and/or remotely from the resource site 200 and also send statuses/updates to other terminals such as the user terminals 314.

The system of FIG. 3 may also include one or more client servers 324 including a processor, memory and communication device. For communication purposes, the client servers 324 may be communicatively coupled to the cloud-computing platform 310, and/or to the user terminals 314a and 314b, and/or to the set of terminals 320 at the resource site 200 and/or to sensors at the oil field, and/or to other equipment at the resource site 200.

A processor, as discussed with reference to the system of FIG. 3, may include a microprocessor, a graphical processing unit (GPU), a microcontroller, a processor module or subsystem, a programmable integrated circuit, a programmable gate array, or another control or computing device.

The memory/storage media discussed above in association with FIG. 3 can be implemented as one or more computer-readable or machine-readable storage media that are non-transitory. In some embodiments, storage media may be distributed within and/or across multiple internal and/or external enclosures of a computing system and/or additional computing systems. Storage media may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories; magnetic disks such as fixed, floppy and removable disks; other magnetic media including tape; optical media such as compact disks (CDs) or digital video disks (DVDs), BluRays or any other type of optical media; or other types of storage devices. “Non-transitory” computer readable medium refers to the medium itself (i.e., tangible, not a signal) and not data storage persistency (e.g., RAM vs. ROM).

Note that instructions can be provided on one computer-readable or machine-readable storage medium, or alternatively, can be provided on multiple computer-readable or machine-readable storage media distributed in a large system having possibly plural nodes and/or non-transitory storage means. Such computer-readable or machine-readable storage medium or media is (are) considered to be part of an article (or article of manufacture). The storage medium or media can be located either in a computer system running the machine-readable instructions, or located at a remote site from which machine-readable instructions can be downloaded over a network for execution.

It is appreciated that the described system of FIG. 3 is an example that may have more or fewer components than shown, may combine additional components, and/or may have a different configuration or arrangement of the components. The various components shown may be implemented in hardware, software, or a combination of both, hardware and software, including one or more signal processing and/or application specific integrated circuits.

Further, the steps in the flowcharts described below may be implemented by running one or more functional modules in an information processing apparatus such as general-purpose processors or application specific chips, such as ASICs, FPGAs, PLDs, GPUs or other appropriate devices associated with the system of FIG. 3. For example, the flowchart of FIG. 1 as well as the flowcharts below may be executed using a signal processing engine/a data processing module (e.g., computing module) stored in memory 306a, 306b, or 306c such that the signal processing engine/data processing module includes instructions that are executed by the one or more processors such as processors 302a, 302b, or 302c as the case may be. The various modules of FIG. 3, combinations of these modules, and/or their combination with general hardware are included within the scope of protection of the disclosure. While one or more computing processors (e.g., processors 302a, 302b, or 302c) may be described as executing steps associated with one or more of the flowcharts described in this disclosure, the one or more computing device processors may be associated with the cloud-based computing platform 310 and may be located at one location or distributed across multiple locations. In one embodiment, the one or more computing device processors may also be associated with other systems of FIG. 3 other than the cloud-computing platform 310.

In some embodiments, a computing system is provided that includes at least one processor, at least one memory, and one or more programs stored in the at least one memory, such that the programs comprise instructions, which when executed by the at least one processor, are configured to perform any method disclosed herein.

In some embodiments, a computer readable storage medium is provided, which has stored therein one or more programs, the one or more programs including instructions, which when executed by a processor, cause the processor to perform any method disclosed herein. In some embodiments, a computing system is provided that includes at least one processor, at least one memory, and one or more programs stored in the at least one memory for performing any method disclosed herein. In some embodiments, an information processing apparatus for use in a computing system is provided for performing any method disclosed herein.

### Flowchart

FIGS. 4A-4B provide an exemplary workflow for methods, systems, and computer programs that dynamically generate a development plan for a resource site based on spatial gradient of time average velocity determinations of a propagated seismic wave. For example, the disclosed techniques may be implemented as a signal processing engine within a geological software tool such that the signal processing engine enables the modeling of geological structures in the subsurface of the resource site based on the processes outlined herein.

At block 402, the signal processing engine may receiving seismic data associated with a subsurface of the resource site. The seismic data, for example, may be associated with a propagated wavefield within the subsurface of the resource site and can comprise at least structural geological data associated with the resource site. At block 404, the signal processing engine may facilitate generating, based on the seismic data, one or more data matrices or data cubes comprising data elements associated with the received seismic data. Furthermore, the signal processing engine may determine, at block 406, using the one or more data matrices or data cubes, a first rate of change data of the propagated wavefield within the subsurface in a first direction. In addition, the signal processing engine may also determine, at block 408, using the one or more data matrices or data cubes, a second rate of change data of the propagated wavefield within the subsurface in a second direction. The signal processing engine, at block 410, may determine, using the one or more data matrices or data cubes, a third rate of change data of the propagated wavefield within the subsurface in a third direction. In some cases, the data processing engine may be used to execute, using the first rate of change data, the second rate of change data, and the third rate of change data, an averaging operation to generate an impedance model for the subsurface at block 412. Turning to block 414, the signal processing engine may generate, using the impedance model of the subsurface, a multi-dimensional image of the subsurface that is resolvable into at least two dimensions or in at least three dimensions as the case may require. At block 416, the signal processing engine may analyze or interpret the multi-dimensional image of the subsurface to determine subsurface features comprised in the multi-dimensional image and thereby generate a geo-layering model for the resource site. Following this, the signal processing engine may dynamically construct, using the geo-layering model, the development plan for the resource site at block 418. The development plan, for example, may comprise a computation report or a digital file indicating structural properties of the subsurface of the resource site including parameters or descriptors of the geo-layering model. At block 420, the signal processing engine may initiate, using the development plan, an energy development operation including deploying one or more energy development equipment to the resource site. This deployment may be facilitated, for example, by the electronic transmission of the development plan to a stake holder (e.g., contractor, site developers, etc.) and/or transmission of instructions to energy development systems that control or otherwise coordinate said deployment of energy development equipment.

In other embodiments, a system and a computer program can include or execute the method described above. These and other implementations may each optionally include one or more of the following features.

The seismic data can comprise one or more of: surface waves including waves whose amplitude decrease with increasing depth within the subsurface of the resource site; guided waves including mechanical or elastic waves within an ultrasonic or a sonic frequency band and which are propagated within a bounded medium; and interface waves indicating geological boundaries comprised in the subsurface of the resource site. In particular, the seismic data can comprise surface waves captured by one or more sensors deployed at the resource site. Furthermore, the one or more sensors deployed at the resource site can comprise one of a distributed acoustic sensor, a hydrophonic sensor, or a geophonic sensor. Moreover, the surface waves can indicate the propagated wavefield within the subsurface of the resource site based on a frequency bandwidth of the propagated wavefield.

In one embodiment, one or more of the first rate of change data, the second rate of change data, and the third rate of change data may be determined based on dispersion analysis of the surface waves, the dispersion analysis being used to determine an estimation of a time average velocity of a propagated wavefield in the first direction, the second direction, and the third direction.

In some cases, a multi-dimensional smoothing process comprising a de-noising operation may be applied to the seismic data prior to determining the first rate of change data, the second rate of change data, or the third rate of change data.

The first direction, the second direction, and the third direction, according to some embodiments, are each orthogonal relative to each other.

According to some embodiments, the averaging operation comprises combining directional rate of change data of the propagated wavefield within the subsurface based on the first rate of change data, the second rate of change data, and the third rate of change data.

Furthermore, analyzing or interpreting the multi-dimensional image of the subsurface can comprise: determining geologic features included in the multi-dimensional image; resolving the geologic features into one or more geological layering data comprised in the subsurface of the resource site; and generating the geo-layering model using the geological layering data.

In addition, the energy development operation can comprise determining geological foundation data for installing equipment associated with a windfarm at the resource site. According to other embodiments, the energy development operation comprises determining a risk map for extracting a resource from the resource site. The risk map, for example, can indicate location data at the resource site that qualifies or quantifies: first risk information for extracting the resource at a first location comprised in the location data and associated with the resource site relative to second risk information for extracting the resource at a second location comprised in the location data and associated with the resource site; and determining hazard information. The hazard information may be used to optimize one or more of: compliance operations associated with the resource site; or security operations including safety operations or insurance operations associated with the resource site.

According to one embodiment, the multi-dimensional image comprises a 2-dimensional or a 3-dimensional image. Furthermore, the multi-dimensional image is resolvable based on the first direction, the second direction, and the third direction.

In some implementations, generating one or more of the first rate of change data, the second rate of change data, and the third rate of change data is based on directionally executing a differentiation operation on the one or more data matrices or data cubes in the first direction, the second direction, or the third direction.

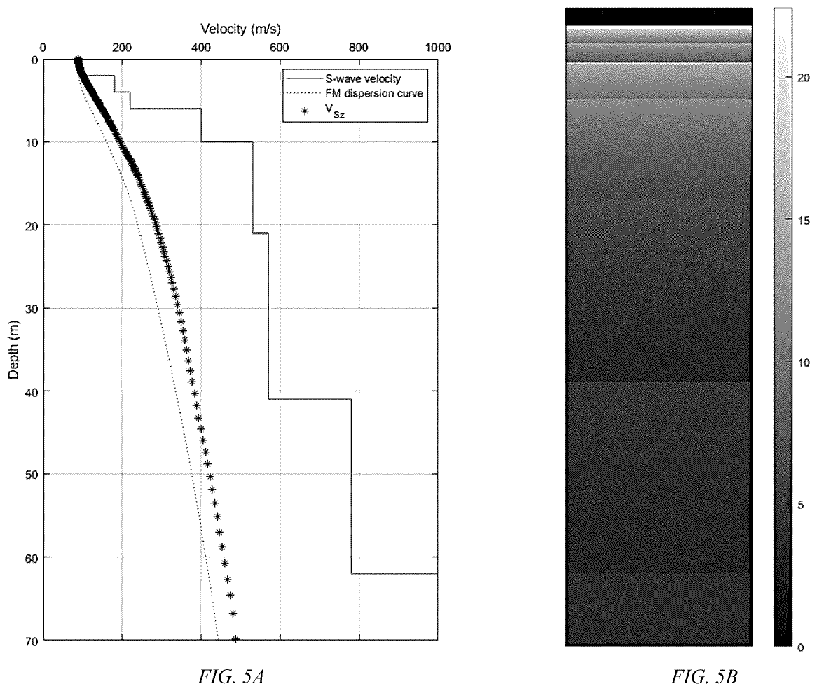

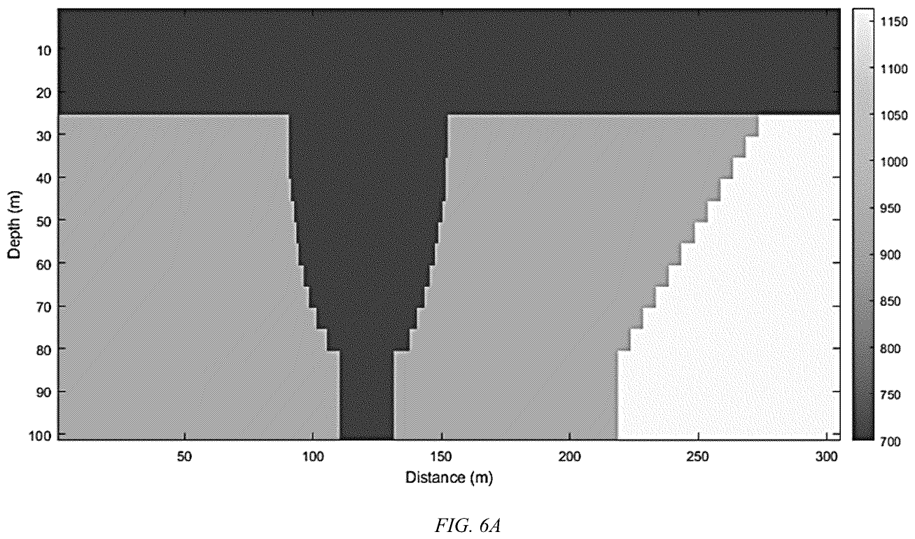

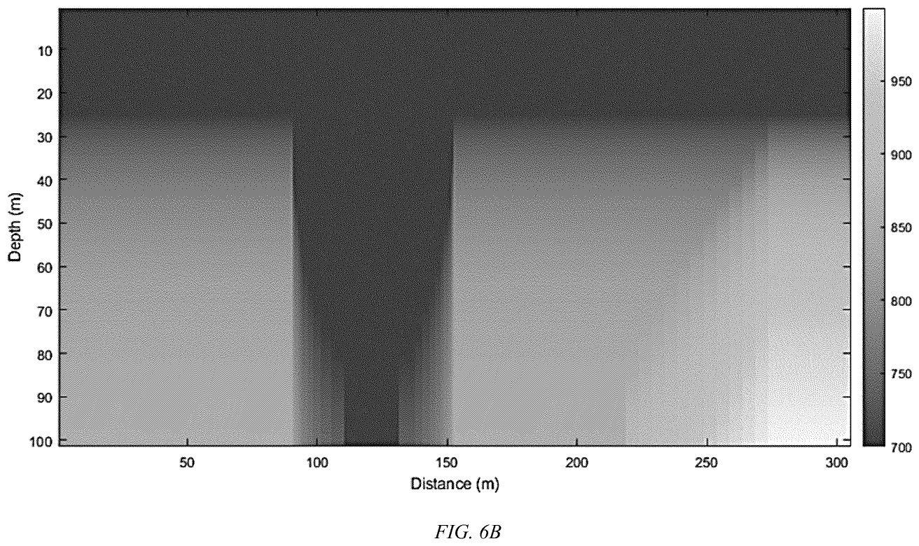

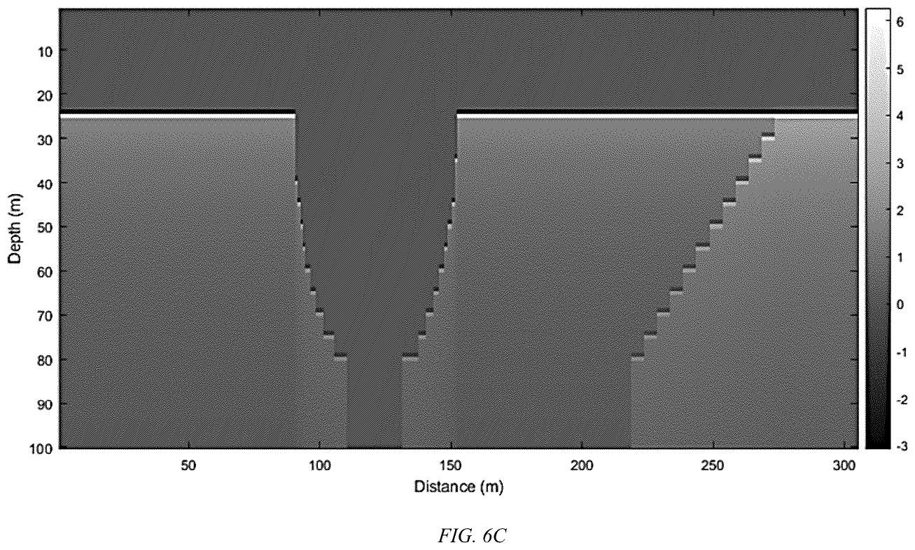

Turning to FIG. 5A, it is appreciated that seismic attributes (e.g., seismic data) in the form of S-wave velocity data together with a dispersion curve of FIG. 5A may be used to generate the time-average S-wave velocity V_{Sz} of FIG. 5A. The geo-layering data shown in FIG. 5B may be obtained by determining (e.g., differentiating) a rate of change of V_{Sz} along a first direction (e.g., a vertical direction) within the subsurface. FIG. 6A depicts an implementation where a synthetic model is used as a reference model to confirm an impedance model (e.g., pseudo-impedance model) of FIG. 6C which is generated by determining (e.g., differentiating) a time-average S-wave velocity V_{Sz} shown in FIG. 6B along a specific direction (e.g., vertical direction) within the subsurface.

While any discussion of or citation to related art in this disclosure may or may not include some prior art references, Applicant neither concedes nor acquiesces to the position that any given reference is prior art or analogous prior art.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to explain the principles of the invention and its practical applications, to thereby enable others skilled in the art to use the invention and various embodiments with various modifications as are suited to the particular use contemplated. It is appreciated that the term optimize/optimal and its variants (e.g., efficient or optimally) may simply indicate improving, rather than the ultimate form of ‘perfection’ or the like.

It will also be understood that, although the terms first, second, etc., may be used herein to describe various elements, these elements should not be limited by these terms. These terms are used to distinguish one element from another. For example, a first object or step could be termed a second object or step, and, similarly, a second object or step could be termed a first object or step, without departing from the scope of the invention. The first object or step, and the second object or step, are both objects or steps, respectively, but they are not to be considered the same object or step.

The terminology used in the description herein is for the purpose of describing particular embodiments and is not intended to be limiting. As used in the description of the invention and the appended claims, the singular forms “a,” “an” and “the” are intended to include the plural forms as well, unless the context clearly indicates otherwise. It will also be understood that the term “and/or” as used herein refers to and encompasses any possible combination of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context.

Those with skill in the art will appreciate that while some terms in this disclosure may refer to absolutes, e.g., all source receiver traces, each of a plurality of objects, etc., the methods and techniques disclosed herein may also be performed on fewer than all of a given thing, e.g., performed on one or more components and/or performed on one or more source receiver traces. Accordingly, in instances in the disclosure where an absolute is used, the disclosure may also be interpreted to be referring to a subset.

What is claimed is:

1. A method for generating a development plan for a resource site, the method comprising:
receiving, using a computer processor, seismic data associated with a subsurface of the resource site, the seismic data being associated with a propagated wavefield within the subsurface of the resource site and includes at least structural geological data associated with the resource site;
generating, using the computer processor and based on the seismic data, one or more data matrices or data cubes including data elements associated with the received seismic data;
determining, using the computer processor and the one or more data matrices or data cubes, a first rate of change data of the propagated wavefield within the subsurface in a first direction;
determining, using the computer processor and the one or more data matrices or data cubes, a second rate of change data of the propagated wavefield within the subsurface in a second direction;
determining, using the computer processor and the one or more data matrices or data cubes, a third rate of change data of the propagated wavefield within the subsurface in a third direction;
executing, using the computer processor and the first rate of change data, the second rate of change data, and the third rate of change data, an averaging operation to generate an impedance model for the subsurface;
generating, using the computer processor and the impedance model of the subsurface, a multi-dimensional image of the subsurface that is resolvable into at least two dimensions;
analyzing or interpreting, using the computer processor, the multi-dimensional image of the subsurface to determine subsurface features included in the multi-dimensional image and thereby generate a geo-layering model;
dynamically constructing, using the computer processor and the geo-layering model, the development plan for the resource site; and
initiating, using the computer processor and the development plan, an energy development operation including deploying one or more energy development equipment at the resource site.

2. The method of claim 1, wherein the seismic data includes one or more of:
surface waves including waves whose amplitude decrease with increasing depth within the subsurface of the resource site;
guided waves including mechanical or elastic waves within an ultrasonic or a sonic frequency band and which are propagated within a bounded medium that is parallel to a direction of the propagated wavefield; and
interface waves indicating geological boundaries included in the subsurface of the resource site.

3. The method of claim 1, wherein the seismic data includes surface waves captured by one or more sensors deployed at the resource site.

4. The method of claim 3, wherein one or more of the first rate of change data, the second rate of change data, and the third rate of change data are determined based on dispersion analysis of the surface waves, the dispersion analysis determining an estimation of a time average velocity of a propagated wavefield in the first direction, the second direction, and the third direction.

5. The method of claim 3, wherein the one or more sensors deployed at the resource site include one of a distributed acoustic sensor, a hydrophone sensor, or a geophone sensor.

6. The method of claim 3, wherein the surface waves indicate the propagated wavefield within the subsurface of the resource site based on a frequency bandwidth of the propagated wavefield.

7. The method of claim 1, wherein a multi-dimensional smoothing process including a de-noising operation is applied to the seismic data prior to determining the first rate of change data, the second rate of change data, or the third rate of change data.

8. The method of claim 1, wherein the first direction, the second direction, and the third direction are each orthogonal relative to each other.

9. The method of claim 1, wherein the averaging operation includes combining directional rate of change data of the propagated wavefield within the subsurface based on the first rate of change data, the second rate of change data, and the third rate of change data.

10. The method of claim 1, wherein analyzing or interpreting the multi-dimensional image of the subsurface comprises:
determining geologic features included in the multi-dimensional image;
resolving the geologic features into one or more geological layering data included in the subsurface of the resource site; and
generating the geo-layering model using the geological layering data.

11. The method of claim 1, wherein the energy development operation includes one or more of:
determining geological foundation data for installing equipment associated with a windfarm at the resource site;
determining a risk map for extracting a resource from the resource site, the risk map indicating location data at the resource site that qualifies or quantifies:
first risk information for extracting the resource at a first location included in the location data and associated with the resource site relative to,
second risk information for extracting the resource at a second location included in the location data and associated with the resource site; and
determining hazard information to optimize one or more of:
compliance operations associated with the resource site, or
security operations at the resource site.

12. The method of claim 1, wherein multi-dimensional image includes a 2-dimensional or a 3-dimensional image.

13. The method of claim 1, wherein generating one or more of the first rate of change data, the second rate of change data, and the third rate of change data is based on directionally executing a differentiation operation on the one or more data matrices or data cubes in the first direction, the second direction, or the third direction.

14. A system for generating a development plan for a resource site, the system comprising:
a computer processor, and
memory storing a data processing engine that includes instructions which are executable by the computer processor to:
receive, seismic data associated with a subsurface of the resource site, the seismic data being associated with a propagated wavefield within the subsurface of the resource site and includes at least structural geological data associated with the resource site;
generate, based on the seismic data, one or more data matrices or data cubes including data elements associated with the received seismic data;
determine, using the one or more data matrices or data cubes, a first rate of change data of the propagated wavefield within the subsurface in a first direction;
determine, using the one or more data matrices or data cubes, a second rate of change data of the propagated wavefield within the subsurface in a second direction;
determine, using the one or more data matrices or data cubes, a third rate of change data of the propagated wavefield within the subsurface in a third direction;
execute, using the first rate of change data, the second rate of change data, and the third rate of change data, an averaging operation to generate an impedance model for the subsurface;
generate, using the impedance model of the subsurface, a multi-dimensional image of the subsurface that is resolvable into at least two dimensions;
analyze or interpret the multi-dimensional image of the subsurface to determine subsurface features included in the multi-dimensional image and thereby generate a geo-layering model;
dynamically construct, using the geo-layering model, the development plan for the resource site; and
initiate, using the development plan, an energy development operation including deploying one or more energy development equipment at the resource site.

15. The system of claim 14, wherein the seismic data includes surface waves captured by one or more sensors deployed at the resource site.

16. The system of claim 14, wherein the first direction, the second direction, and the third direction are each orthogonal relative to each other

17. The system of claim 14, wherein the averaging operation includes combining directional rate of change data of the propagated wavefield within the subsurface based on the first rate of change data, the second rate of change data, and the third rate of change data

18. The system of claim 14, wherein the energy development operation includes one or more of:
determining geological foundation data for installing equipment associated with a windfarm at the resource site;
determining a risk map for extracting a resource from the resource site, the risk map indicating location data at the resource site that qualifies or quantifies:
first risk information for extracting the resource at a first location included in the location data and associated with the resource site relative to,
second risk information for extracting the resource at a second location included in the location data and associated with the resource site; and
determining hazard information to optimize one or more of:
compliance operations associated with the resource site, or
security operations at the resource site.

19. A computer program for generating a development plan for a resource site, the computer program including a non-transitory computer-readable medium including code configured to:
receive, seismic data associated with a subsurface of the resource site, the seismic data being associated with a propagated wavefield within the subsurface of the resource site and includes at least structural geological data associated with the resource site;
generate, based on the seismic data, one or more data matrices or data cubes including data elements associated with the received seismic data;
determine, using the one or more data matrices or data cubes, a first rate of change data of the propagated wavefield within the subsurface in a first direction;
determine, using the one or more data matrices or data cubes, a second rate of change data of the propagated wavefield within the subsurface in a second direction;
determine, using the one or more data matrices or data cubes, a third rate of change data of the propagated wavefield within the subsurface in a third direction;
execute, using the first rate of change data, the second rate of change data, and the third rate of change data, an averaging operation to generate an impedance model for the subsurface;
generate, using the impedance model of the subsurface, a multi-dimensional image of the subsurface that is resolvable into at least two dimensions;
analyze or interpret the multi-dimensional image of the subsurface to determine subsurface features included in the multi-dimensional image and thereby generate a geo-layering model;
dynamically construct, using the geo-layering model, the development plan for the resource site; and
initiate, using the development plan, an energy development operation including deploying one or more energy development equipment at the resource site.

20. The computer program of claim 19, wherein the energy development operation includes one or more of:
determining geological foundation data for installing equipment associated with a windfarm at the resource site;
determining a risk map for extracting a resource from the resource site, the risk map indicating location data at the resource site that qualifies or quantifies:
first risk information for extracting the resource at a first location included in the location data and associated with the resource site relative to,
second risk information for a second location included in the location data and associated with the resource site; and
determining hazard information to optimize one or more of:
compliance operations associated with the resource site, or
security operations at the resource site.
